(19) United States
(12) Patent Application Publication
(10) Pub. No.: US 2025/0109494 A1
(43) Pub. Date: Apr. 3, 2025

(54) METHODS AND SYSTEMS FOR PREVENTIVE MAINTENANCE OF SEMICONDUCTOR PROCESSING EQUIPMENT

(71) Applicant: ASM IP Holding B.V., Almere (NL)

(72) Inventor: Kenneth Honniball, Kessel-Lo (Leuven) (BE)

(21) Appl. No.: 18/904,974

(22) Filed: Oct. 2, 2024

Related U.S. Application Data
(60) Provisional application No. 63/542,177, filed on Oct. 3, 2023.

(51) Int. Cl. C23C 16/44; C23C 16/455; C23C 16/52

(52) U.S. Cl. CPC C23C 16/4405; C23C 16/4412; C23C 16/45553; C23C 16/52; C23C 16/4408

(57) ABSTRACT

Methods and related systems that can be useful in the field of semiconductor processing equipment. Methods as disclosed herein can comprise cleaning a precursor line with a hot gas stream emanating from a hot end of a vortex tube.

### CROSS-REFERENCE TO RELATED APPLICATION(S)

This Application claims the benefit of U.S. Provisional Application 63/542,177 filed on Oct. 3, 2023, the entire contents of which are incorporated herein by reference.

### FIELD OF INVENTION

The present disclosure is in the field of integrated circuit manufacture, and in particular in the field of preventive maintenance of semiconductor production tools.

### BACKGROUND OF THE DISCLOSURE

Many semiconductor processes use precursor chemicals. Over time or perhaps due to human error the chemical condenses or deposits in the gas line or in component internals. This leads to a failing particle spec. resulting in wafer product damage. Removing those particles using state-of-the-art techniques can take a lot of time. Therefore, there is a need for improved maintenance methods.

### SUMMARY OF THE DISCLOSURE

In one aspect, described herein is a system comprising a precursor source, a process chamber, a precursor line, and a cleaning device; the precursor source comprising a precursor vessel; and, the precursor line fluidly connecting the precursor source to the process chamber; wherein the cleaning device comprises a vortex tube having a hot end and a cold end, the hot end being operationally connected to the precursor line to execute a precursor line clean.

In some embodiments, the precursor line clean comprises cleaning the precursor line with a hot gas stream emanating from the hot end of the vortex tube.

In some embodiments, the system further comprises a controller, the controller being constructed and arranged for causing the system to alternatingly execute a plurality of depositions and the precursor line clean, wherein ones from the plurality of depositions comprise at least one of atomic layer deposition and chemical vapor deposition.

In some embodiments, the system further comprises a particle filter, the particle filter being disposed downstream from the vortex tube and upstream from the precursor line.

In some embodiments, the system further comprises a valve, the valve being disposed downstream from the vortex tube and upstream from the precursor line.

In some embodiments, the valve is disposed downstream from the particle filter.

In some embodiments, the valve comprises a check valve.

In some embodiments, the hot gas stream has a temperature of at least 100° C.

In some embodiments, the system further comprises a cleaning exhaust valve constructed and arranged for opening and closing the precursor line, the cleaning exhaust valve being positioned downstream from the vortex tube.

In some embodiments, the cleaning exhaust valve is positioned adjacent to the process chamber.

In some embodiments, the process chamber comprises a substrate support, the substrate support comprising a substrate detector.

In some embodiments, the controller is constructed and arranged for causing the system to execute a precursor line clean when the substrate detector detects the absence of a substrate.

In some embodiments, the system further comprises a heater jacket, the heater jacket being arranged around the precursor line.

In some embodiments, the heating jacket is constructed and arranged for creating an increasing temperature gradient from the precursor source to the process chamber.

In a further aspect, described herein is a method for cleaning a precursor line, the method comprising: providing a system comprising a precursor source comprising a precursor, a process chamber, a precursor line fluidly connecting the precursor source and the process chamber, and a vortex tube having a hot end and a cold end, wherein the precursor line comprises a particulate contaminant; and, cleaning the precursor line by providing, via the vortex tube, a hot gas stream to the precursor line, thereby at least partially removing the particulate contaminant from the precursor line.

In some embodiments, the hot gas stream has a temperature of at least 100° C.

In some embodiments, the method further comprises heating the precursor line by means of a heating jacket.

In some embodiments, the system further comprises a run counter, the run counter incrementing when a process employing the precursor has been executed in the process chamber, wherein the step of cleaning the precursor line is executed when the run counter has exceeded a pre-determined value.

In some embodiments, the run counter is reset after the step of cleaning the precursor line has been executed.

In some embodiments, the system further comprises a heater jacket, the heater jacket being arranged around the precursor line, and wherein cleaning the precursor line comprises heating the precursor line by means of the heating jacket while providing the hot gas stream to the precursor line.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1-3 show embodiments of systems according to the present disclosure.

FIG. 4 shows an embodiment of a precursor line.

FIG. 5 shows an embodiment of a method as disclosed herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

When the terms “downstream” and “upstream” are used in the present disclosure, reference is made to the relative position of two parts or objects along a gas stream. In particular, an object or part is downstream with respect to another when the direction of gas flow is followed in going from the latter to the former. Conversely, a first object or part is upstream from a second object or part when the direction of gas flow is followed in going from the first object to the second object.

When one part or object is adjacent to another, the two parts in question can be close by or abutting. For example, the distance between these two parts can be less than 10 cm, or less than 5 cm, or less than 2 cm, or less than 1 cm, or less than 1 mm, or substantially 0 mm.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein are systems, sub systems, and methods for particle abatement. The presently disclosed subject matter is particularly applicable in the field of semiconductor device processing in which particle control is of key importance. The presently disclosed subject matter includes employing vortex tubes for heating precursor lines, thereby efficiently removing particles from said precursor lines.

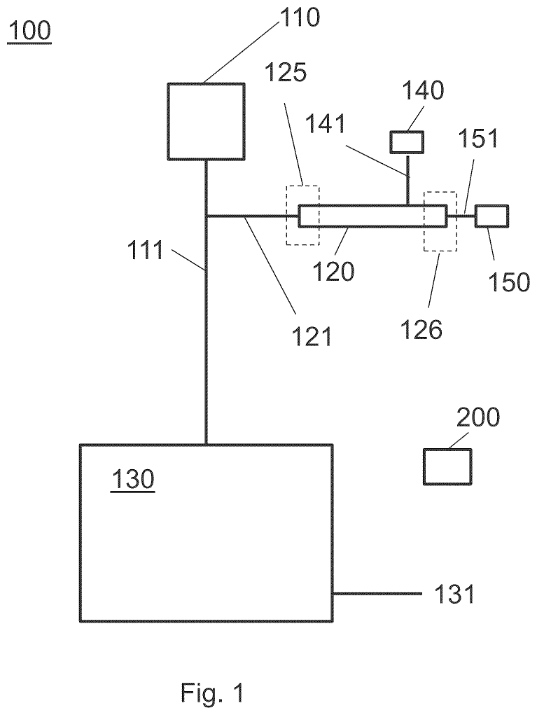

Referring to FIG. 1, disclosed herein is an embodiment of a system 100. The system 100 comprises a precursor source 110, a process chamber 130, a precursor line 111, and a vortex tube 120. The precursor source 110 can comprise a precursor vessel. The precursor vessel can comprise a precursor. Suitable precursors are known in the art and include atomic layer deposition (ALD) precursors and chemical vapor deposition (CVD) precursors. The precursor line 111 fluidly connects the precursor source 110 to the process chamber 130. The vortex tube 120 has a hot end 125 and a cold end 126. The hot end 125 is operationally, i.e. fluidly, connected to the precursor line 111. Thus, a precursor line clean can be executed by means of the vortex tube 120. The precursor line clean can comprise cleaning the precursor line with a hot gas stream emanating from the hot end of the vortex tube. By means of the hot gas stream, the precursor line can be efficiently and time efficiently cleaned. Conversely, attempting to clean a precursor line by alternatingly flowing a cold gas stream through it and then evacuating, e.g. at room temperature, can take hours to days, without any guarantee that the particle count will come within spec.

Thus, described herein is a system that comprises a precursor source, a process chamber, a precursor line, and a cleaning device. The precursor source can comprise a precursor vessel. The precursor vessel can comprise a precursor. The precursor line can fluidly connect the precursor source to the process chamber. The cleaning device can comprise a vortex tube that has a hot end and a cold end. The hot end can be operationally connected to the precursor line to execute a precursor line clean.

In some embodiments, the vortex tube 120 can comprise a hot end 125 and a cold end 126. The hot end 125 can be fluidly connected to the precursor line 111 by means of a hot gas line 121. The cold end 126 can be fluidly connected to a cold outlet 150 by means of a cold outlet line 151. Pressurized gas can be fed to the vortex tube by means of a gas inlet 140 and a gas inlet line 141.

In some embodiments, the system 100 further comprises a controller 200. The controller 200 can be constructed and arranged for causing the system 100 to alternatingly execute a plurality of depositions and the precursor line clean.

In some embodiments, ones from the plurality of depositions comprise at least one of atomic layer deposition and chemical vapor deposition.

After passing through the precursor line 111, the hot gas stream can be removed from the system 100 by any suitable means. For example, the hot gas stream can be removed from the system 100 through a reaction chamber exhaust line 131.

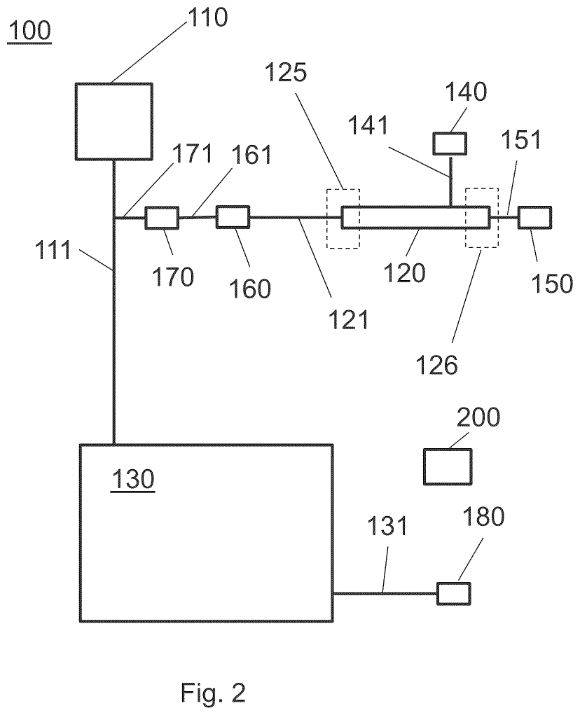

Further embodiments of systems according to the present disclosure are described with reference to FIG. 2 which particularly shows another embodiment of a system 100 as described herein. The system 100 of the embodiment of FIG. 2 comprises the features of the system 100 of the embodiment of FIG. 1, and in addition can comprise a number of additional features. In particular, in some embodiments, the system 100 further comprises a particle filter 160. The particle filter 160 can be positioned downstream from the vortex tube 120 and upstream from the precursor line 111. Suitable particle filters comprise woven or non-woven heat-resistant fabrics, such as metal or ceramic felts. Suitable metal felts include stainless steel felts. Suitable ceramic felts include alumina felts.

In some embodiments, a reaction chamber exhaust 180 can receive exhaust gas from the process chamber 130 by means of the reaction chamber exhaust line 131.

In some embodiments, the system 100 further comprises a valve 170. The valve 170 can be disposed downstream from the vortex tube 120 and upstream from the precursor line 111. In some embodiments, the valve 170 comprises a check valve. Suitably, the valve 170 can be disposed downstream from the particle filter 160. Thus, the valve 170 can be protected from particles by the particle filter 160, which can extend its useful life.

In some embodiments, the particle filter 160 and the valve 170 can be fluidly connected by means of a post particle segment 161, which can be or can comprise a piece of tubing. In some embodiments, the particle filter 160 can be fluidly connected to the hot end 125 by means of the hot gas line 121, which can be or can comprise a piece of tubing. In some embodiments, the valve 170 can be fluidly connected to the precursor line 111 by means of a post valve segment 171

After passing through the precursor line 111, the hot gas stream can be removed from the system 100 by any suitable means. For example, the hot gas stream can be removed from the system 100 through the reaction chamber exhaust 180 via the reaction chamber exhaust line 131.

In some embodiments, the hot gas stream has a temperature of at least 100° C. For example, the hot gas stream can have a temperature of at least 100° C. to at most 1000° C., or of at least 100° C. to at most 200° C., or of at least 200° C. to at most 500° C., or of at least 500° C. to at most 1000° C. In some embodiments, the hot gas stream has a temperature of about 200° C.

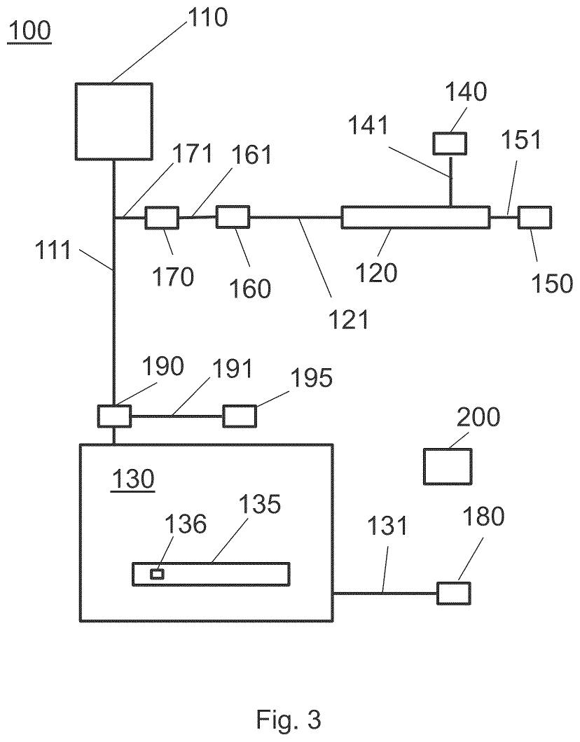

Further embodiments of systems according to the present disclosure are described with reference to FIG. 3 which particularly shows another embodiment of a system 100 as described herein. The system 100 of the embodiment of FIG. 2 comprises the features of the system 100 of the embodiment of FIG. 1, and in addition can comprise a number of additional features. The system 100 can further comprise a cleaning exhaust valve 190 which can be constructed and arranged for opening and closing the precursor line 111, the cleaning exhaust valve 190 can be positioned downstream from the vortex tube 120. Suitably, the cleaning exhaust valve 190 can be positioned adjacent to the process chamber 130.

In some embodiments, the process chamber comprises a substrate support 135. The substrate support 135 can comprise a substrate detector 136. Suitable substrate supports can include pedestals, susceptors, wafer boats and the like. Some substrate supports, such as pedestals or susceptors, can hold one substrate. Some substrate supports, such as wafer boats, can contain a plurality of substrates. Suitable substrate detectors include inductive detectors, capacitive detectors, and piezoelectric sensors

In some embodiments, the controller 200 is constructed and arranged for causing the system 100 to execute a precursor line clean when the substrate detector 136 detects the absence of a substrate.

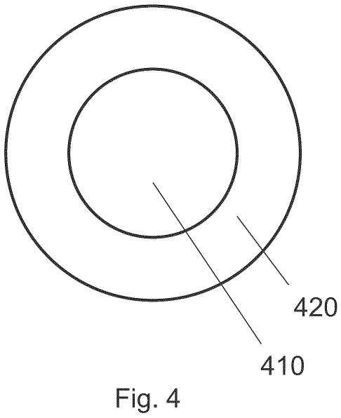

In some embodiments, the system 100 comprises a heater jacket 420, the heater jacket 420 can be arranged around the precursor line 410. This is illustrated by means of FIG. 4

In some embodiments, the heating jacket is constructed and arranged for creating an increasing temperature gradient from the precursor source to the process chamber. This can be done, for example, using a segmented heating jacket that is operated to dissipate various amounts of electric power at different locations of a precursor line. In some embodiments, cleaning the precursor line comprises heating the precursor line by means of the heating jacket while providing the hot gas stream to the precursor line via the vortex tube.

In some embodiments, the system further comprises a run counter. For example, the run counter can be comprised in the controller. Suitably, the run counter can comprise a memory for storing an integers. Such an integer can increment when a process that employs the precursor has been executed in the process chamber. In such embodiments, the step of cleaning the precursor line is executed when the run counter has exceeded a pre-determined value. Thus, the precursor line can be automatically cleaned periodically to ensure that the amount of particulate matter in the precursor line remains under control.

In some embodiments, the controller can be constructed and arranged for resetting the run counter after the step of cleaning the precursor line has been executed. Thus, the controller can contain a memory for storing a pre-determined run number, and whenever the run counter has reached or exceeded that pre-determined run number, the precursor line can be automatically cleaned by means of the vortex tube.

After passing through the precursor line 111, the hot gas stream can be removed from the system 100 by any suitable means. For example, the hot gas stream can be removed from the system 100 through the reaction chamber exhaust 180 via the reaction chamber exhaust line 131. Additionally or alternatively, the hot gas stream, or a part thereof, can be removed from the system 100 through a cleaning exhaust valve 190. The cleaning exhaust valve 190 can be comprised in or on the precursor line 111 and can be positioned upstream from the process chamber 130. The cleaning exhaust valve 190 can be fluidly connected with a cleaning exhaust 195 by means of a cleaning exhaust duct 191.

Further described herein is a method for cleaning a precursor line. The method can comprise a step of providing a system, such as a system according to an embodiment of the present disclosure. The system can comprise a precursor source that comprises a precursor, a process chamber, a precursor line that fluidly connects the precursor source and the process chamber, and a vortex tube having a hot end and a cold end. The precursor line comprises a contaminant, such as a particulate contaminant. In other words, the precursor line can comprise particles, such as precursor particles, or partially or wholly decomposed precursor particles. Cleaning the precursor line can comprise providing a hot gas stream to the precursor line by means of the vortex tube. Thus the contaminant, e.g. particulate contaminant, can be removed at least partially from the precursor line.

In some embodiments, a presently described method can comprise heating the precursor line by means of a heating jacket.

In some embodiments, the hot gas stream comprises, consists of, or substantially consists of an inert or a substantially inert gas. Suitable gasses include noble gasses such He, Ne, Ar, Kr, and Xe. In some embodiments, the hot gas stream comprises, consists of, or substantially consists of N₂.

In some embodiments, the hot gas stream comprises, consists of, or substantially consists of a reactive gas. Suitable gasses include oxygen-containing gasses such as O₂ and H₂O. In some embodiments, the hot gas stream comprises, consists of, or substantially consists of H₂. In some embodiments, the hot gas stream comprises, consists of, or substantially consists of forming gas. Forming gas can refer to a mixture of H₂ in N₂, e.g. of 5 to 50 mol % H₂ in N₂.

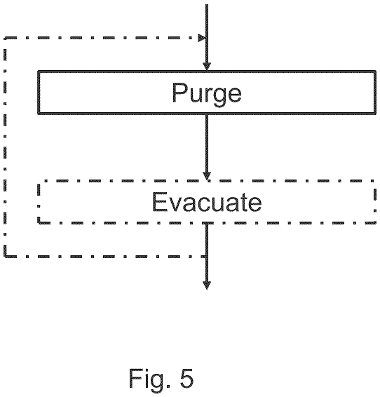

In some embodiments, a presently disclosed method can comprise evacuating a precursor line after purging the precursor line with a hot gas stream. In some embodiments, a presently disclosed method can comprise cyclically purging a precursor line with a hot gas stream and evacuating the precursor line. Such embodiments are illustrated by way of FIG. 5. Evacuating the precursor line can comprise removing purge gas from the precursor line by means of a vacuum pump.

1. A system comprising a precursor source, a process chamber, a precursor line, and a cleaning device;
the precursor source comprising a precursor vessel; and,
the precursor line fluidly connecting the precursor source to the process chamber; wherein the cleaning device comprises a vortex tube having a hot end and a cold end, the hot end being operationally connected to the precursor line to execute a precursor line clean.

2. The method according to claim 1, wherein the precursor line clean comprises cleaning the precursor line with a hot gas stream emanating from the hot end of the vortex tube.

3. The system according to claim 1, further comprising a controller, the controller being constructed and arranged for causing the system to alternatingly execute a plurality of depositions and the precursor line clean, wherein ones from the plurality of depositions comprise at least one of atomic layer deposition and chemical vapor deposition.

4. The system according to claim 1, further comprising a particle filter, the particle filter being disposed downstream from the vortex tube and upstream from the precursor line.

5. The system according to claim 1, further comprising a valve, the valve being disposed downstream from the vortex tube and upstream from the precursor line.

6. The system according to claim 5, wherein the valve is disposed downstream from the particle filter.

7. The system according to claim 5, wherein the valve comprises a check valve.

8. The system according to claim 2, wherein the hot gas stream has a temperature of at least 100° C.

9. The system according to claim 1, further comprising a cleaning exhaust valve constructed and arranged for opening and closing the precursor line, the cleaning exhaust valve being positioned downstream from the vortex tube.

10. The system according to claim 9, wherein the cleaning exhaust valve is positioned adjacent to the process chamber.

11. The system according to claim 1, wherein the process chamber comprises a substrate support, the substrate support comprising a substrate detector.

12. The system according to claim 11, wherein the controller is constructed and arranged for causing the system to execute a precursor line clean when the substrate detector detects the absence of a substrate.

13. The system according to claim 11, further comprising a heater jacket, the heater jacket being arranged around the precursor line.

14. The system according to claim 13, wherein the heating jacket is constructed and arranged for creating an increasing temperature gradient from the precursor source to the process chamber.

15. A method for cleaning a precursor line, the method comprising:
providing a system comprising a precursor source comprising a precursor, a process chamber, a precursor line fluidly connecting the precursor source and the process chamber, and a vortex tube having a hot end and a cold end, wherein the precursor line comprises a particulate contaminant; and,
cleaning the precursor line by providing, via the vortex tube, a hot gas stream to the precursor line, thereby at least partially removing the particulate contaminant from the precursor line.

16. The method according to claim 15 wherein the hot gas stream has a temperature of at least 100° C.

17. The method according to claim 15, further that further comprises heating the precursor line by means of a heating jacket.

18. The method according to claim 15, wherein the system further comprises a run counter, the run counter incrementing when a process employing the precursor has been executed in the process chamber, wherein the step of cleaning the precursor line is executed when the run counter has exceeded a pre-determined value.

19. The method according to claim 18, wherein the run counter is reset after the step of cleaning the precursor line has been executed.

20. The method according to claim 15, wherein the system further comprises a heater jacket, the heater jacket being arranged around the precursor line, and wherein cleaning the precursor line comprises heating the precursor line by means of the heating jacket while providing the hot gas stream to the precursor line.
